(19) United States
(12) Patent Application Publication
(10) Pub. No.: US 2004/0061195 A1
(43) Pub. Date: Apr. 1, 2004

(54) Semiconductor device and manufacturing method thereof

(75) Inventors: Tetsuya Okada, Kumagaya-city (JP); Mitsuhiro Yoshimura, Ora-gun (JP)

Correspondence Address: ROTHWELL, FIGG, ERNST & MANBECK, P.C., 1425 K STREET, N.W., SUITE 800, WASHINGTON, DC, 20005, US

(73) Assignee: Sanyo Electric Co., Ltd., Moriguchi-city (JP)

(21) Appl. No.: 10/673,541

(22) Filed: Sep. 30, 2003

(30) Foreign Application Priority Data
Sep. 30, 2002 (JP) 2002-285651

(51) Int. Cl. H01L 27/095

(52) U.S. Cl. 257/477

(57) ABSTRACT

Hithereto, there was a problem involving that the VF and IR characteristics of a Schottky barrier diode were in a tradeoff relationship, and an increase in leak current was unavoidable to implement low VF. In some preferred embodiments, a plurality of P⁺-type orthohexagonal semiconductor regions are provided in a Schottky junction region. Since they are spaced from one another equidistantly, depletion layers are spread from the P⁺-type semiconductor regions when a reverse voltage is applied, and are fully filled in an epitaxial layer. As a result, a leak current occurring at the Schottky junction interface can be prevented from leaking to the cathode side. Even when a high leak current occurs, it can be intercepted by the depletion layers, so that the tradeoff relationship between VF and IR can be eliminated. Thus, a low VF can be implemented without consideration for IR.

### BACKGROUND OF THE INVENTION

1. Field of the Invention

The present invention relates to semiconductor devices and to manufacturing methods thereof, and certain preferred embodiments relate, in particular, to semiconductor devices and manufacturing methods thereof to enhance the low VF/low IR characteristics of a Schottky barrier diode.

2. Description of the Related Art

A Schottky junction formed by a silicon semiconductor substrate and a metal layer provides an element which is generally well known as a Schottky barrier diode because it has a rectifying action based on the barrier of the Schottky junction.

FIGS. 8(A)-8(B) show a conventional Schottky barrier diode. FIG. 8(A) is a plan view, and FIG. 8(B) is a cross-sectional view taken along the line B-B of FIG. 8(A).

An N⁻-type epitaxial layer 2 is laminated on an N-type semiconductor substrate 1. In addition, a Schottky metal layer 6 is formed on the surface of the N-type epitaxial layer 2 to form a Schottky junction in cooperation with the surface of the N⁻-type epitaxial layer 2. The metal layer can be formed of Ti, for example. Furthermore, an Al layer serving as an anode electrode 7 is formed so as to cover the whole surface of the metal layer. A high-concentration impurity region 4 is provided on the outer periphery of the semiconductor substrate by diffusing P⁺-type impurities in order to secure a withstanding voltage, and a part of the impurity region 4 is brought into contact with the Schottky metal layer 6.

When metal and a semiconductor substrate which are different in work function come into contact with each other, their energy band diagrams are varied so that the Fermi levels thereof are coincident with each other, thereby forming a Schottky barrier therebetween. The height of the barrier (i.e., the difference in work function—in this specification, the difference in work function will be hereinafter represented by ΦBn) is a factor for determining the characteristics of a Schottky barrier diode. ΦBn is a value inherent to metal.

When a negative voltage is applied to the N-type silicon side of the Schottky barrier diode while a positive voltage is applied to the metal layer side, current flows in the Schottky barrier diode, and the voltage at this time is a forward voltage VF. On the other hand, when the voltage application direction is inverted, such that a positive voltage is applied to the N-type silicon side while a negative voltage is applied to the metal layer side, no current flows. The voltage at this time will be hereinafter referred to as a reverse voltage. The Schottky metal layer of the Schottky barrier diode can be considered as a pseudo P-type region.

With regards to some Schottky barrier diodes, the forward voltage VF of the Schottky barrier diode increases as ΦBn becomes larger. Conversely, the leak current IR, when the reverse voltage is applied, is reduced. That is, the forward voltage VF and the leak current IR have a tradeoff relationship with each other.

Now, a method for manufacturing a conventional Schottky barrier diode will be described with reference to FIGS. 9(A)-9(C).

First, the N⁻-type epitaxial layer 2 is laminated on the N⁺-type semiconductor substrate 1, and a high-concentration impurity region 4 is formed in the peripheral portion of the substrate by doping and diffusing P⁺-type impurities to secure a predetermined withstand voltage (FIG. 9(A)).

Thereafter, the Schottky metal layer 6 such as Ti or the like is deposited on the surface of the epitaxial layer 2. Then, a heat treatment for silicidation is carried out thereby forming a Schottky junction between the epitaxial layer and the metal layer. Since ΦBn varies in accordance with the Schottky metal layer and the Schottky junction region, the Schottky metal layer is appropriately selected in consideration of the size of a chip and the desired characteristics (FIG. 9(B)).

Furthermore, the Al layer serving as the anode electrode 7 is formed on the whole surface. In addition, a cathode electrode 8 is formed on the back surface to achieve a final structure (FIG. 9(C)).

As described above, in the conventional Schottky barrier diode, the Schottky metal layer is deposited substantially on the whole surface of the N⁻-type epitaxial layer (see: Japanese Patent Application Publication No. Hei 6-224410).

The forward voltage VF corresponding to the rise-up voltage of the Schottky barrier diode and the leak current IR under application of the reverse voltage are determined by ΦBn achieved by the Schottky junction between the Schottky metal layer and the semiconductor substrate. FIG. 10 shows the relationship between ΦBn, VF and IR. As shown in FIG. 10, they have a tradeoff relationship such that when ΦBn is high, VF increases and IR decreases.

For the same ΦBn, the values of VF and IR are varied in accordance with the Schottky junction area.

Therefore, with the Schottky barrier diode, ΦBn is selected in accordance with the Schottky junction area (i.e., the chip size), so that the characteristics approach the desired characteristics by the tradeoff of the VF and IR characteristics.

For example, when the Schottky barrier diode is applied to a small-signal field, the chip size is small and, thus, IR is relatively reduced. Therefore, a low VF is preferential and, thus, a low ΦBn is adopted. On the other hand, when the Schottky barrier diode is applied to a large-signal field, the chip size is required to be large to some extent, and, thus, the effect of the leak current IR is relatively large. Therefore, priority is given to suppression of the leak current IR. Thus, a high ΦBn is adopted.

Here, the value of ΦBn is inherent to metal. It is difficult to select this value in a detailed range. Furthermore, in the calculation of the values of VF and IR, variation in ΦBn causes a great change in the values of VF and IR. For example, a low ΦBn is used in a small-signal system, for the above reasons, and the forward voltage VF is a rise-up voltage of a device as described above. Therefore, ΦBn is desirably low in efficient utilization of a power source voltage. When it is required to reduce VF, it is a general solution to increase the junction area because a change of ΦBn varies the characteristics significantly. However, an increase of the junction area makes the chip size larger, and this increases the costs and impedes miniaturization.

Existing semiconductor devices and methods had a variety of limitations. The present invention was made in view of these and/or other limitations in the related art.

### SUMMARY OF THE INVENTION

The preferred embodiments of the present invention can provide substantial improvements over the above-mentioned and/or other devices and methods in the related art.

The preferred embodiments of the present invention can overcome the above and/or other problems of existing devices, by, e.g., providing a semiconductor device comprising a one-conduction type semiconductor substrate, a one-conduction type semiconductor layer formed on the substrate, a plurality of first reverse-conduction type semiconductor regions formed in the semiconductor layer, a second reverse-conduction type semiconductor region formed in the peripheral portion of the semiconductor layer so as to surround the plurality of first reverse-conduction type semiconductor regions, and a metal layer forming Schottky junctions in cooperation with the semiconductor layer and the surfaces of the first reverse-conduction type semiconductor regions.

Furthermore, the first reverse-conduction type semiconductor regions can be formed by burying reverse-conduction type semiconductor material into trenches formed in the semiconductor layer.

In addition, the first reverse-conduction type semiconductor regions can also be formed by diffusing reverse-conduction type impurities into the semiconductor layer.

The respective neighboring first reverse-conduction type semiconductor regions are preferably disposed so as to be spaced from each other at an interval so that the semiconductor layer between neighboring first reverse-conduction type semiconductor regions is fully filled in the depletion layer when reverse voltages are applied to the Schottky barrier diode.

The respective neighboring first reverse-conduction type semiconductor regions are preferably disposed so as to be spaced from one another at substantially equal intervals.

The first reverse-conduction type semiconductor regions are preferably formed with a thickness smaller than the thickness of the semiconductor layer.

The second reverse-conduction type semiconductor region can be a diffusion region.

The second reverse-conduction type semiconductor region can also be formed by burying semiconductor material into a plurality of trenches formed in the semiconductor layer.

According to some embodiments, a semiconductor device can be provided that includes: a one-conduction type semiconductor substrate; a one-conduction type semiconductor layer formed on the substrate; at least one reverse-conduction type semiconductor region formed in the semiconductor layer; a metal layer forming a Schottky junction area in cooperation with the semiconductor layer and surfaces of the at least one reverse-conduction type semiconductor region; and the at least one reverse-conduction type semiconductor region being configured such that the semiconductor layer in a Schottky junction area is fully filled in a depletion layer when a reverse voltage is applied. In some examples, the at least one reverse-conduction type semiconductor region includes: a plurality of first reverse-conduction type semiconductor regions formed in the semiconductor layer; and a second reverse-conduction type semiconductor region formed around the semiconductor layer so as to surround the plurality of first reverse-conduction type semiconductor regions.

According to some embodiments, a semiconductor device is provided that includes: a substrate; a semiconductor layer on the substrate; a metal layer forming a Schottky junction area in cooperation with the semiconductor layer; means for fully filling the semiconductor layer in the Schottky juntion area in a depletion layer when a reverse voltage is applied such as to pinch off the semiconductor layer so as to suppress an IR leak current. In some examples, the means for fully filling includes: a plurality of first reverse-conduction type semiconductor regions formed in the semiconductor layer; and a second reverse-conduction type semiconductor region formed around the semiconductor layer so as to surround the plurality of first reverse-conduction type semiconductor regions.

In addition, the preferred embodiments of the present invention can overcome the above and/or other problems of existing methods by, e.g., providing a method including: laminating a one-conduction type semiconductor layer on a one-conduction type semiconductor substrate; forming, in the semiconductor layer, a plurality of first reverse-conduction type semiconductor regions and a second reverse-conduction type semiconductor region surrounding the first reverse-conduction type semiconductor regions; and forming a metal layer that forms Schottky junctions in cooperation with the semiconductor layer and surfaces of the first reverse-conduction type semiconductor regions.

The first reverse-conduction type semiconductor regions can be formed by ion-implanting and diffusing impurities.

The first reverse-conduction type semiconductor regions can also be formed by forming trenches in the semiconductor layer and burying reverse-conduction type semiconductor material in the trenches.

The second reverse-conduction type semiconductor region can be formed by forming a plurality of trenches in the semiconductor layer and burying reverse-conduction type semiconductor material in the trenches.

The first reverse-conduction type semiconductor regions and the second reverse-conduction type semiconductor region can be simultaneously formed.

One feature of the preferred embodiments resides in that a plurality of P⁺-type semiconductor regions are provided in the semiconductor layer at an equal interval. This can suppress an increase in the leak current IR caused by increasing the reverse voltage while keeping the VF characteristics at the same level as in the related art. When the reverse voltage is applied, the leak current corresponding to the Schottky metal layer occurs at the interface between the semiconductor layer and the Schottky metal layer. However, according to the structure of the preferred embodiments, the leak current can be intercepted by the depletion layer fully filled in the semiconductor layer, and leakage to the back-surface electrode side can be prevented.

In addition, a Schottky metal layer having a ΦBn of low VF can be adopted without taking the leak current IR into consideration. The P⁺-type semiconductor regions become invalid regions when the forward voltage is applied to the Schottky barrier diode. It is preferable for the Schottky barrier diode of which the junction area between the Schottky metal layer and the semiconductor layer is large because the VF can be reduced. According to the structure of some of the preferred embodiments, the Schottky junction area is reduced. However, this can be solved by changing the Schottky metal layer to a metal layer having a lower ΦBn. The metal layer having a low ΦBn can reduce the VF, but it increases IR. However, a large leak current occurring at the interface of the Schottky junction can be intercepted by the depletion layer. Thus, a metal layer having ΦBn which can obtain a predetermined VF can be adopted without taking the leak current into consideration.

As described above, a leak current occurring at the interface of the Schottky junction is unavoidable. However, the preferred embodiments are advantageous in that the leak current thus occurring is pinched off and intercepted by the depletion layer which is spread in the semiconductor layer by the PN junction. Since there is no current leak to the cathode electrode side (i.e., it is unnecessary to pay attention to IR), the tradeoff relationship problem of VF and IR of the related art can be eliminated. It is, thus, possible to design a device in consideration of only VF.

Furthermore, according to manufacturing methods of the preferred embodiments, first, the P⁺-type semiconductor regions can be formed simultaneously with the high-concentration impurity region which is an indispensable constituent element of the Schottky barrier diode. In some embodiments, when polysilicon is buried in the trenches, the number of steps is increased. However, a Schottky barrier diode which can control the VF characteristics can be manufactured without changing the chip size. That is, as compared to the related art, a Schottky barrier diode having a low VF and a low IR can be manufactured without increasing the costs. Furthermore, if a diffusion region of impurities is employed as the P⁺-type semiconductor regions 3, similar steps as in the related art can be used by merely changing the mask.

In addition, if the P⁺-type semiconductor regions 3 are formed after the high-concentration impurity region 4 is formed, the number of steps is increased. However, a Schottky barrier diode having a high withstanding voltage can be implemented.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### DESCRIPTION OF THE DRAWINGS

The accompanying figures are provided by way of example, without limiting the broad scope of the invention or various other embodiments, wherein:

FIG. 1(A) is a plan view, FIG. 1(B) is a cross-sectional view, and FIG. 1 (C) is a cross-sectional view for explaining a semiconductor device according to the preferred embodiments.

FIG. 2 is a characteristics diagram for explaining the semiconductor device according to the preferred embodiments.

FIG. 3 is a cross-sectional view for explaining a method for manufacturing the semiconductor device according to the preferred embodiments.

FIG. 4 is a cross-sectional view for explaining the method for manufacturing the semiconductor device according to the preferred embodiments.

FIG. 5 is a cross-sectional view for explaining the method for manufacturing the semiconductor device according to the preferred embodiments.

FIG. 6 is a cross-sectional view for explaining the method for manufacturing the semiconductor device according to the preferred embodiments.

FIG. 7 is a cross-sectional view for explaining the method for manufacturing the semiconductor device according to the preferred embodiments.

FIG. 8(A) is a plan view and FIG. 8(B) a cross-sectional view for explaining a conventional semiconductor device.

FIG. 9 is a cross-sectional view for explaining a method for manufacturing the conventional semiconductor device shown in FIG. 8.

FIG. 10 is a characteristics diagram for explaining the conventional semiconductor device shown in FIG. 8.

### DESCRIPTION OF THE PREFERRED EMBODIMENTS

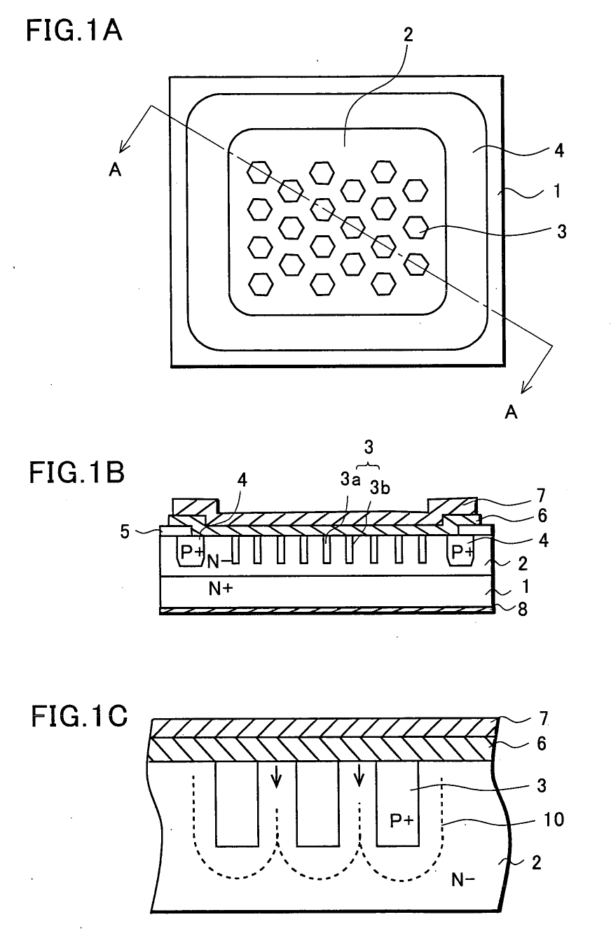

A number of preferred embodiments of the present invention will now be described in detail with reference to FIGS. 1 through 7. While some exemplary embodiments are described, these illustrative embodiments are merely exemplary (i.e., shown by way of example) and do not limit the broad scope of the invention.

FIG. 1 shows a Schottky barrier diode according to the preferred embodiments of this invention. FIG. 1(A) is a plan view. FIG. 1(B) is a cross-sectional view taken along with the line A-A of FIG. 1(A). And, FIG. 1(C) is an enlarged view of FIG. 1(B). In FIG. 1(A), the Schottky metal layer and the anode electrode on the surface of the substrate are omitted from the illustration.

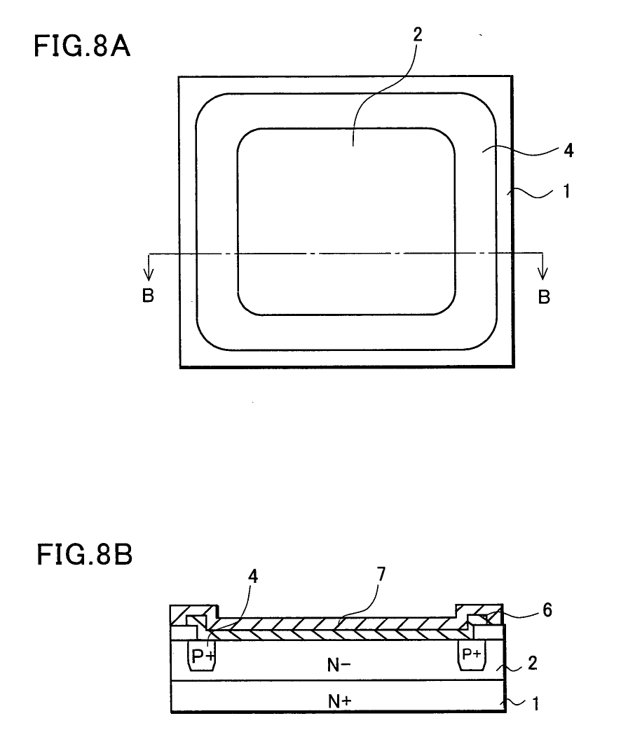

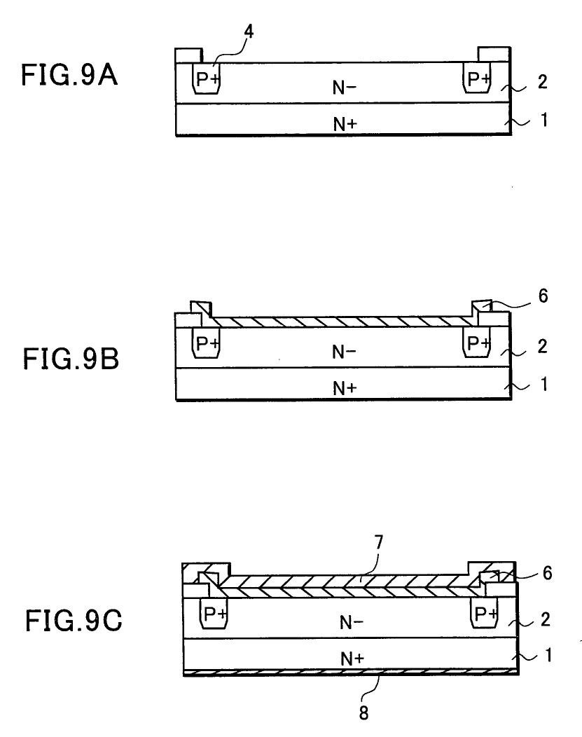

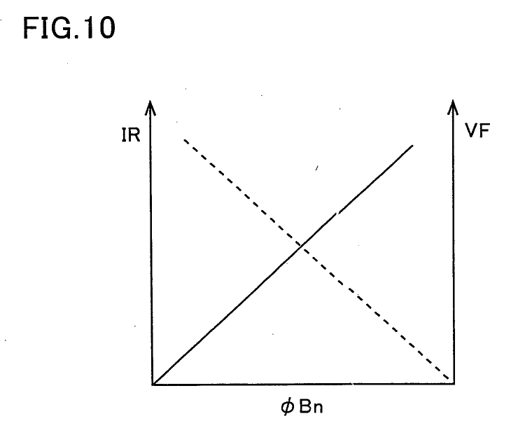

The Schottky barrier diode of the preferred embodiments of this invention include a one-conduction type semiconductor substrate 1, a one-conduction type semiconductor layer 2, a plurality of first reverse-conduction type semiconductor regions 3, a second reverse-conduction type semiconductor region 4 and a Schottky metal layer 6. In FIGS. 1(A)-1(C), similar constituent elements to that shown in FIGS. 8 and 9 are represented by similar reference numerals.

The first reverse-conduction type semiconductor regions 3 correspond to P⁺-type semiconductor regions formed in the N⁻-type epitaxial layer 2 laminated on the N⁺-type semiconductor substrate 1. In this region, in some embodiments, trenches 3a are formed in the epitaxial layer 2, and polysilicon 3b containing P⁺-type impurities is buried in the trenches 3a. Then, a heat treatment is carried out to diffuse the P⁺-type impurities into the surrounding portions of the trenches, thereby forming the P⁺-type semiconductor regions 3. In preferred embodiments, each trench 3a has an orthohexagonal shape. In some embodiments, each trench (e.g., each orthodexagonal trench) has an opening width (e.g., a diagonal width) of about 1 μm, for example. In some embodiments, a large number of such trenches 3a are formed in the epitaxial layer 2 and are preferably each spaced from one another at an interval of approximately 1 μm to 10 μm. As described in detail below, it is preferred that the P⁺-type semiconductor regions 3 are designed in an orthohexagonal shape because the neighboring P⁺-type semiconductor regions 3 are desired to be arranged at equal intervals (such as, e.g., shown in FIGS. 1(A)-1(C)).

The second reverse-conduction semiconductor region 4 corresponds to a P⁺-type high-concentration impurity region provided so as to surround the outer circumference of all the P⁺-type semiconductor regions 3 to secure the withstanding voltage when the reverse voltage is applied to the Schottky barrier diode. The high-concentration impurity region 4 is formed to have a width of approximately 20 μm in consideration of misalignment of a mask because a part thereof is to be brought into contact with the Schottky metal layer 6. A plurality of trenches 3a having the same pattern as the P⁺-type semiconductor regions 3 are formed in a line-and-space pattern, and then buried with P⁺-type polysilicon 3b. By a heat treatment which is carried out after polysilicon 3b is buried, the impurities in polysilicon 3b are diffused and the impurity regions are unified, thereby forming the high-concentration impurity region 4 having a large width. Furthermore, in some embodiments, the region can be formed by ion-implanting or diffusing P⁺-type impurities like the related art.

Preferably, all of the P⁺-type semiconductor regions 3 disposed inside the high-concentration impurity region 4 and the epitaxial layer 2 serve as a Schottky junction region.

The Schottky metal layer 6 can be formed of Mo or the like, for example. As described below, the metal layer 6 can be appropriately selected in consideration of VF and IR. The metal layer 6 is formed on the epitaxial layer 2 and all the P⁺-type semiconductor regions 3 to form Schottky junctions. An Al layer or the like is formed as an anode electrode 7 on the Schottky metal layer 6. In addition, a cathode electrode 8 is formed on the back surface of the N⁺-type semiconductor substrate 1. In the conventional structure, it is only the epitaxial layer 2 that is brought into contact with the Schottky metal layer 6 inside of the high-concentration region 4 provided at the outermost peripheral portion (the Schottky junction region). However, in the structure of the preferred embodiments, the epitaxial layer 2 and the P⁺-type semiconductor regions 3 are brought into contact with the Schottky metal layer 6 inside of the high concentration region 4 (see, e.g., FIG. 1(B)).

The preferred embodiments of the invention include that the plurality of P⁺-type semiconductor regions 3 are arranged in the epitaxial layer 2 at equal intervals. The Schottky metal layer 6 of the Schottky barrier diode can be considered as a pseudo P-type region, and it comes into contact with the P⁺-type semiconductor regions 3. That is, the Schottky metal layer 6 and the P⁺-type semiconductor regions 3 can be regarded as a continuous P-type region.

Accordingly, when a reverse voltage is applied to the Schottky barrier diode, as shown by dotted lines in FIG. 1(c), a depletion layer 10 spreads in the epitaxial layer 2 between the P⁺-type semiconductor regions 3 by the PN junction between the N-type epitaxial layer 2 in cooperation with the P⁺-type semiconductor regions 3 and the Schottky metal layer 6. As described above, each of the P⁺-type semiconductor regions 3 are preferably spaced from one another at substantially a predetermined equal interval. The predetermined interval can be set to a value so that the epitaxial layer 2 is fully filled with the depletion layer 10 spreading from the P⁺-type semiconductor regions when the reverse voltage is applied (see, e.g., FIG. 1(C)). In preferred embodiments, the interval is set to approximately 1 μm to 10 μm.

In the structure of the preferred embodiments of the invention, the leak current corresponding to the type of Schottky metal layer 6 occurs at the interface between the epitaxial layer 2 and the Schottky metal layer 6 when the reverse voltage is applied as in the case of the related art. However, when the reverse voltage (VR) reaches a certain level, the depletion layer 10 is fully filled in the epitaxial layer 2 and pinches off the epitaxial layer 2. In this manner, the leak current occurring at the interface is intercepted and current leakage to the cathode electrode 8 side can be prevented. That is, an increase in leak current (IR) due to an increase in the reverse voltage (VR) can be suppressed by retaining the characteristics which can secure the same forward-voltage VF of the related art.

Here, the P⁺-type semiconductor regions 3 become invalid regions when the forward voltage is applied to the Schottky barrier diode. It is desirable for the Schottky barrier diode that the junction region between the Schottky metal layer 6 and the epitaxial layer 2 is large because the forward voltage (VF) can be reduced. On the other hand, according to the structure of the preferred embodiments of the invention, the Schottky junction area is reduced. However, this problem can be solved by changing the Schottky metal layer to one having a lower ΦBn. In the case of a metal layer having a low ΦBn, although the forward voltage (VF) can be reduced, the leak current (IR) is increased. However, even when the leak current IR at the interface of the Schottky junction is increased, it can be intercepted by the depletion layer 10. That is, a metal layer having a ΦBn that provides a predetermined forward voltage VF can be employed without consideration for the leak current IR.

Thus, according to the preferred embodiments of the invention, the tradeoff relationship between VF and IR which has hitherto been a problem can be eliminated. Accordingly, in some embodiments, it is possible to design products in consideration of only VF.

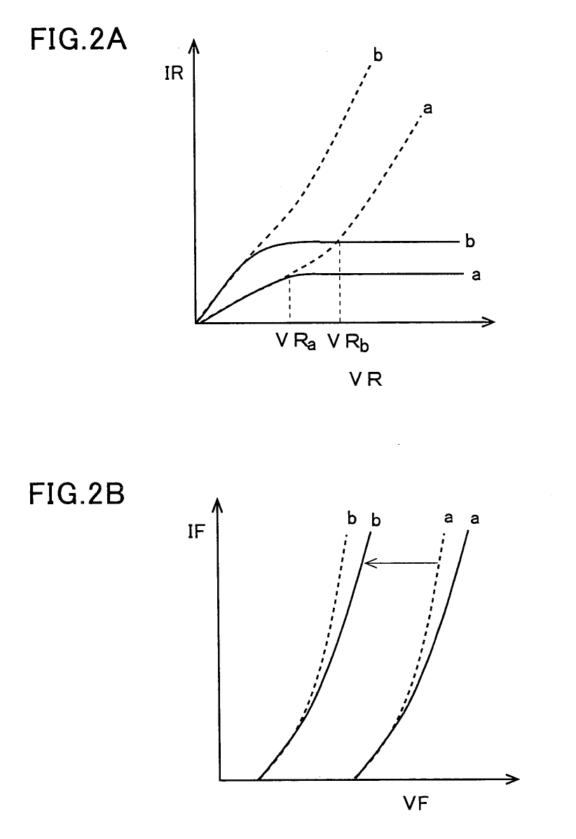

Additional details of some preferred embodiments will now be explained with reference to the characteristic diagram of FIGS. 2(A)-2(B). FIG. 2(A) shows the relationship between the reverse voltage VR and the leak current IR when the reverse voltage is applied. FIG. 2(B) shows the relationship between the forward voltage (VF) and the forward current (IF). The solid lines indicate the characteristics according to a preferred embodiment of this invention. The dotted lines illustrate the characteristics according to a conventional structure. In the figures, “a” represents a case where a metal layer having a high ΦBn (such as, for example, Mo) is used, and “b” represents a case where a metal layer having a low ΦBn (such as, for example, Ti) is used.

According to the structure of the preferred embodiment of this invention, the characteristics of the Schottky barrier diode can be created as indicated by the solid lines “a” and “b” of FIG. 2(A). As shown, the same characteristics as in the conventional structure are exhibited at the initial stage. However, when the reverse voltage (VR) is increased, spreading of the depletion layer 10 causes pinch-off at VRa and VRb in accordance with ΦBn. Then, an increase in the leak current IR can be suppressed.

The provision of the P⁺-type semiconductor regions 3 reduces the Schottky junction area. Therefore, as compared with the conventional structure using metal having a high ΦBn as indicated by the dotted line “a” of FIG. 2(B), the forward voltage VF increases in the structure of these embodiments using the same metal which is indicated by the solid line “a”. However, in such a case, the problem can be solved by adopting a metal layer having a low ΦBn indicated by the solid line “b”. When the increase in VF greatly affects the device, the forward voltage VF can be reduced by adopting a metal layer having a lower ΦBn (e.g., solid line “b”) as compared with the conventional structure (dotted line “a”) adopting a high ΦBn.

In FIG. 2(A), the solid line “b” shows a case where a metal layer having a low ΦBn is adopted in the structure of some embodiments. That is, at the reverse voltage VRb, IR can be suppressed by inverting the conventional structure of the high ΦBn metal layer (dotted line “a”). As described above, a low VF and a low IR are made compatible with each other by appropriately selecting ΦBn.

As described above, the preferred embodiments of this invention can be advantageous in that, for example, even when the leak current occurs at the Schottky junction interface, the leak current can be intercepted by the deletion layer. The leak current at the Schottky junction region interface is unavoidable. However, the leak current at the Schottky barrier diode can be suppressed if no current leaks to the cathode electrode side. That is, the leak current due to an increase in the reverse voltage can be suppressed by using even the same Schottky metal layer as in the related art although the forward voltage VF is slightly increased.

Furthermore, if the Schottky junction area is reduced and the forward voltage VF is increased by providing the P⁺-type semiconductor regions 3, a metal layer having a low ΦBn of VF can be used. An increase in the leak current IR under application of the reverse voltage can be suppressed by pinch-off at some voltage, and the characteristics of the conventional structure using a metal layer having a high ΦBn can be inverted. Thus, a tradeoff relationship between VF and IR can be eliminated.

Here, the optimum shape of each of the P⁺-type semiconductor regions 3 is orthohexagonal because they are each desired to be disposed at equal intervals from one another so that the depletion layer 10 spreads uniformly under application of the reverse voltage and is fully filled in the epitaxial layer 2. Even when there is only one place at which spreading of the depletion layer is insufficient, current would leak from the place to the cathode electrode 8 side. Therefore, in various alternative embodiments, as long as the interval between the respective neighboring P⁺-type semiconductor regions 3 is kept at such a distance that the depletion layer 10 is fully filled therebetween, the shape of the P⁺-type semiconductor regions 3 is not limited to the orthohexagonal shape, but can be any other shape or configuration as would be understood by those in the art based on this disclosure.

In some embodiments, when the interval distance between the P⁺-type semiconductor regions 3 can be secured to a certain extent, P⁺-type impurities can be ion-implanted and diffused into the epitaxial layer 2 by using a mask having, e.g., orthohexagonal openings to form diffusion regions. However, when the interval distance is small, spreading in the lateral direction is unavoidable in the impurity diffusion regions. Therefore, it is preferable to use P⁺-type semiconductor regions 3 achieved by burying polysilicon 3b in trenches 3a (e.g., as described above).

Next, some methods for manufacturing a Schottky barrier diode according to the preferred embodiments of the invention will be described in detail with reference to FIGS. 3 through 7.

The manufacturing methods according to the preferred embodiments of this invention can include, e.g., a step of laminating a one-conduction type semiconductor layer 2 on a one-conduction type semiconductor substrate 1, a step of forming, in the semiconductor layer 2, a plurality of first reverse-conduction type semiconductor regions 3 and a second reverse-conduction type semiconductor region 4 surrounding the first reverse-conduction type semiconductor regions 3, and a step of forming a metal layer 6 that forms Schottky junctions in cooperation with the semiconductor layer 2 and the surfaces of the first reverse-conduction type semiconductor regions 3.

A first step of the preferred embodiments of this invention is to laminate the one-conduction type semiconductor layer 2 on the one-conduction type semiconductor substrate 1 as shown in FIG. 3.

The N⁻-type epitaxial layer 2 is laminated on the N⁺-type semiconductor substrate 1, and an oxide film (not shown) is formed on the overall surface of the N⁻-type epitaxial layer 2. While omitted from FIG. 3, the oxide film on the outermost periphery of the substrate is opened, and N⁺-type impurities are deposited through the opening and then diffused, thereby forming an annular ring.

A second step of the preferred embodiments of this invention is to form in the semiconductor layer 2 a plurality of first reverse-conduction type semiconductor regions 3 and the second reverse-conduction type semiconductor region 4 surrounding the outer circumference of the plurality of first reverse-conduction type semiconductor regions 3.

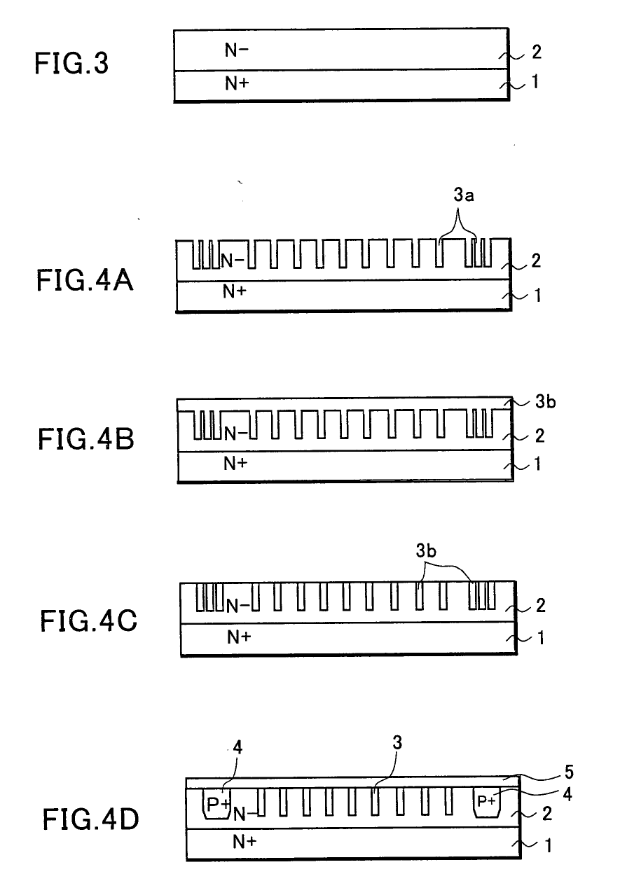

FIGS. 4(A)-4(D) show a first embodiment of the second step.

In this regard, a first embodiment of the second step includes simultaneous formation of the P⁺-type semiconductor regions 3 and the high-concentration impurity region 4.

In FIG. 4(A), the trenches 3a are formed in the epitaxial layer 2 by, e.g., using a mask having hexagonal openings of approximately 1 μm in an opening width (e.g., in a diagonal width) formed therein. The trenches 3a serve to form a number of P⁺-type semiconductor regions 3, and also serve to form a high-concentration impurity region 4 surrounding the outer circumference of the plurality of P⁺-type semiconductor regions 3. The P⁺-type semiconductor regions 3 are disposed so as to be spaced from one another at substantially equal intervals so that the epitaxial layer 2 is fully filled with the depletion layer when the reverse voltage is applied. A plurality of trenches 3a for the high-concentration impurity region 4 are disposed, for example, in a line-and-space pattern of 1 μm by using a similar hexagonal pattern.

In FIG. 4(B), polysilicon 3b doped with P⁺-type impurities is preferably buried in all trenches 3a. The P⁺-type impurities can be introduced after non-doped polysilicon is deposited on the overall surface, or the polysilicon doped with the P⁺-type impurities can be deposited. Thereafter, as shown in FIG. 4(C), the overall surface is preferably etched back, polysilicon 3b is buried in the trenches 3a, and the surface of the epitaxial layer 2 and the surfaces of the predetermined P⁺-type semiconductor regions 3 and the high-concentration impurity region 4 to be formed are exposed.

In FIG. 4(D), the P⁺-type semiconductor regions 3 are preferably activated by forming an oxide film 5 to thereby form the P⁺-type semiconductor regions 3. At the same time, on the outer periphery, a minute amount of P⁺-type impurities is diffused from the plurality of adjacent trenches by, e.g., a heat treatment, and the impurity regions are unified, thereby forming a high-concentration impurity region 4 having a large width of approximately 20 μm. The high-concentration impurity region 4 is required to come into contact with the Schottky metal layer. Accordingly, the high-concentration impurity region 4 is desired to have a certain extent of width in consideration of the potential misalignment of a mask.

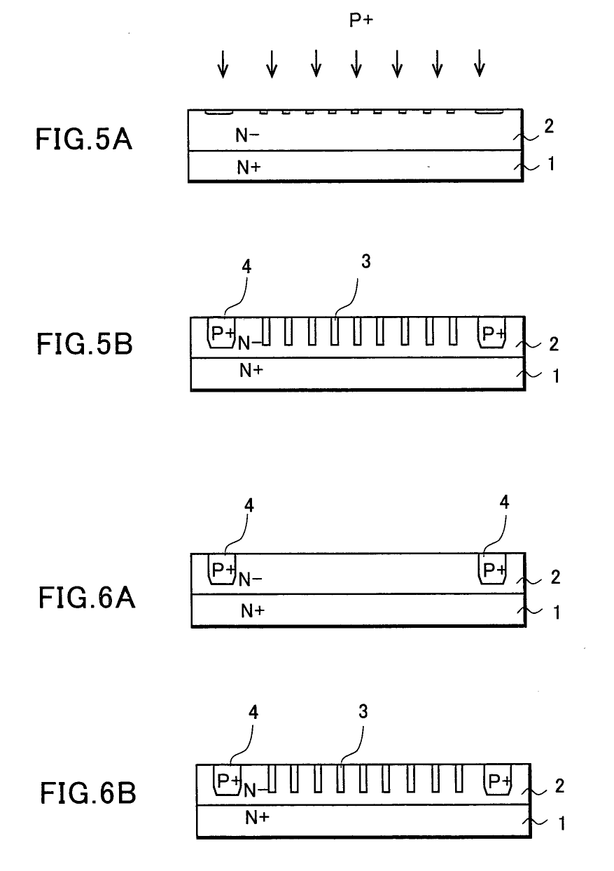

FIG. 5 shows embodiments in which the P⁺-type semiconductor regions 3 and the high-concentration impurity region 4 are formed by ion-implantation and diffusion of P⁺-type impurities. If both the condition for fully filling the depletion layer between the P⁺-type semiconductor regions 3 and the condition for securing a predetermined width in consideration of the misalignment in the high-concentration impurity region 4 are combined with each other, the P⁺-type semiconductor regions 3 and the high-concentration impurity region 4 can be formed simultaneously in the diffusion region where the impurities are ion-implanted and then diffused.

As described above, according to the manufacturing method of the first embodiment of the second step, the P⁺-type semiconductor regions 3 can be formed simultaneously with the high-concentration impurity region 4 which is a notable constituent element of the Schottky barrier diode. When they are formed by burying polysilicon 3b in the trenches 3a, this step is added. However, a Schottky barrier diode which can control the VF characteristic without changing the chip size can be manufactured. That is, as compared to the related art, a Schottky barrier diode having a low VF can be manufactured without increasing the cost. Furthermore, if the impurities-diffusion regions are employed as the P⁺-type semiconductor regions 3, the process can be executed by merely changing the mask for forming the high-concentration impurity region 4 in the conventional step.

Next, a second embodiment of the second step will be described with reference to FIGS. 6(A)-6(B).

For example, in a Schottky barrier diode having a high withstanding voltage, the high-concentration impurity region 4 can be formed more deeply than the trenches 3a. Furthermore, it is preferable to have a large curvature in the sectional shape. In such cases, it can be better to form the P⁺-type semiconductor regions 3 and the high-concentration impurity region 4 in different steps.

In this regards, the P⁺-type impurities are preferably first doped into the outer periphery of the Schottky junction region as shown in FIG. 6(A), and then diffused to form the high-concentration impurity region 4. From the viewpoint of the sectional shape, the curvature around the bottom portion can be moderated because of the diffusion region, and concentration of the electric field onto this portion can be suppressed. Therefore, this embodiment is suitable for, e.g., a device type having a high withstanding voltage. Thereafter, the trenches 3a are preferably formed in the epitaxial layer 2 as shown in FIG. 6(B), and P⁺-type polysilicon 3b is buried in the trenches 3a to form the P⁺-type semiconductor regions 3. Alternatively, after P+impurities are doped, the P⁺-type semiconductor regions 3 can be formed by diffusing the P⁺-impurities.

As described above, in the case of the second embodiment, the number of steps increases in comparison to the first embodiment, but a Schottky barrier diode having a high withstanding voltage can be implemented.

The third step of the preferred embodiments of this invention is to form the metal layer 6 which forms the Schottky junctions in cooperation with the semiconductor layer 2 and the surfaces of the first reverse-conduction type semiconductor regions 3.

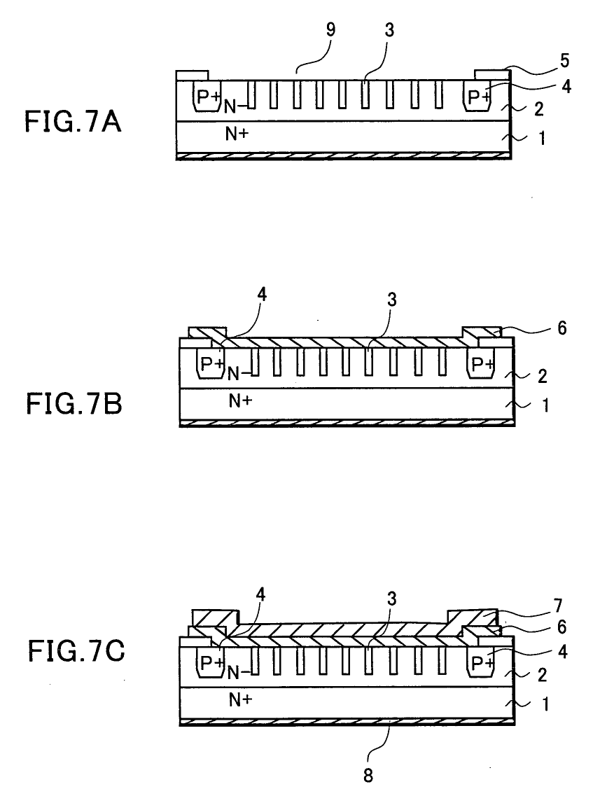

As shown in FIG. 7(A), the oxide film 5 adhering to the overall surface by a diffusion step or the like is preferably removed, and the Schottky junction region 9 (i.e., the surfaces of all the P⁺-type semiconductor regions 3 and the epitaxial layer 2) are exposed. In order to bring the high-concentration impurity region 4 into contact with the Schottky metal layer 6, a part thereof is exposed (such as, e.g., shown). That is, the oxide film 5 inside the high-concentration impurity region 4, containing a part of the high-concentration impurity region 4, is removed by, e.g., etching to expose the Schottky junction region 9.

Furthermore, as shown in FIG. 7(B), Mo, for example, is deposited as the Schottky metal layer 6. It is patterned in a desired shape covering at least the Schottky junction region 9. Then, an anneal treatment is preferably carried out at about 500 to 600° C. for silicidation. Here, for example, the P⁺-type semiconductor regions 3 of the Schottky junction region 9 become invalid regions at the time of forward bias. Therefore, Ni, Cr, Ti or the like which have a low ΦBn may be used in place of, e.g., Mo.

Thereafter, as shown in FIG. 7(C), the Al layer serving as the anode electrode 7 is preferably deposited on the overall surface and patterned in a desired shape. In addition, cathode electrode 8 of Ti-Ni-Au or the like is formed on the back surface, thereby achieving the final structure (such as, e.g., shown in FIG. 1(B)).

Broad Scope of the Invention

While illustrative embodiments of the invention have been described herein, the present invention is not limited to the various preferred embodiments described herein, but includes any and all embodiments having modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” Means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited.

What is claimed is:

1. A semiconductor device, comprising:
a one-conduction type semiconductor substrate;
a one-conduction type semiconductor layer formed on the substrate;
a plurality of first reverse-conduction type semiconductor regions formed in the semiconductor layer;
a second reverse-conduction type semiconductor region formed around the semiconductor layer so as to surround the plurality of first reverse-conduction type semiconductor regions; and
a metal layer forming Schottky junctions in cooperation with the semiconductor layer and surfaces of the first reverse-conduction type semiconductor regions.

2. The semiconductor device according to claim 1, wherein the first reverse-conduction type semiconductor regions are formed by burying reverse-conduction type semiconductor material into trenches formed in the semiconductor layer.

3. The semiconductor device according to claim 1, wherein the first reverse-conduction type semiconductor regions are formed by diffusing reverse-conduction type impurities into the semiconductor layer.

4. The semiconductor device according to claim 1, wherein the respective neighboring first reverse-conduction type semiconductor regions are disposed so as to be spaced from one another at such intervals that the semiconductor layer between neighboring first reverse-conduction type semiconductor regions is fully filled in a depletion layer when reverse voltages are applied.

5. The semiconductor device according to claim 1, wherein respective neighboring first reverse-conduction type semiconductor regions are disposed so as to be spaced from one another at substantially equal intervals.

6. The semiconductor device according to claim 1, wherein the first reverse-conduction type semiconductor regions are formed with a thickness smaller than the thickness of the semiconductor layer.

7. The semiconductor device according to claim 1, wherein the second reverse-conduction type semiconductor region is a diffusion region.

8. The semiconductor device according to claim 1, wherein the second reverse-conduction type semiconductor region is formed by burying semiconductor material into a plurality of trenches formed in the semiconductor layer.

9. A method for manufacturing a semiconductor device, comprising:
laminating a one-conduction type semiconductor layer on a one-conduction type semiconductor substrate;
forming, in the semiconductor layer, a plurality of first reverse-conduction type semiconductor regions and a second reverse-conduction type semiconductor region surrounding the plurality of first reverse-conduction type semiconductor regions; and
forming a metal layer that forms Schottky junctions in cooperation with the semiconductor layer and surfaces of the first reverse-conduction type semiconductor regions.

10. A method for manufacturing a semiconductor device according to claim 9, wherein the first reverse-conduction type semiconductor regions are formed by ion-implanting and diffusing impurities.

11. A method for manufacturing a semiconductor device according to claim 9, wherein the first reverse-conduction type semiconductor regions are formed by forming trenches in the semiconductor layer and burying reverse-conduction type semiconductor material in the trenches.

12. A method for manufacturing a semiconductor device according to claim 9, wherein the second reverse-conduction type semiconductor region is formed by forming a plurality of trenches in the semiconductor layer and burying reverse-conduction type semiconductor material in the trenches.

13. A method for manufacturing a semiconductor device according to claim 9, wherein the first reverse-conduction type semiconductor regions and the second reverse-conduction type semiconductor region are simultaneously formed.

14. A semiconductor device, comprising:
a one-conduction type semiconductor substrate;
a one-conduction type semiconductor layer formed on the substrate;
at least one reverse-conduction type semiconductor region formed in the semiconductor layer;
a metal layer forming a Schottky junction area in cooperation with the semiconductor layer and surfaces of the at least one reverse-conduction type semiconductor region; and
said at least one reverse-conduction type semiconductor region being configured such that the semiconductor layer in a Schottky junction area is fully filled in a depletion layer when a reverse voltage is applied.

15. The semiconductor device of claim 14, wherein said at least one reverse-conduction type semiconductor region includes: a plurality of first reverse-conduction type semiconductor regions formed in the semiconductor layer; and a second reverse-conduction type semiconductor region formed around the semiconductor layer so as to surround the plurality of first reverse-conduction type semiconductor regions.

16. A semiconductor device, comprising:
a substrate;
a semiconductor layer on the substrate;
a metal layer forming a Schottky junction area in cooperation with the semiconductor layer;
means for fully filling the semiconductor layer in the Schottky juntion area in a depletion layer when a reverse voltage is applied such as to pinch off the semiconductor layer so as to suppress an IR leak current.

17. The semiconductor device of claim 16, wherein the means for fully filling includes: a plurality of first reverse-conduction type semiconductor regions formed in the semiconductor layer; and a second reverse-conduction type semiconductor region formed around the semiconductor layer so as to surround the plurality of first reverse-conduction type semiconductor regions.
